(19) United States
(12) Patent Application Publication
(10) Pub. No.: US 2021/0223336 A1
(43) Pub. Date: Jul. 22, 2021

(54) APPARATUS AND METHOD FOR IMPROVING THE SENSITIVITY OF MAGNETIC FIELD SENSORS

(71) Applicant: Spincoil Systems, Inc., Burlingame, CA (US)

(72) Inventor: Waldo HINSHAW, Burlingame, CA (US)

(21) Appl. No.: 17/154,303

(22) Filed: Jan. 21, 2021

Related U.S. Application Data
(60) Provisional application No. 62/963,877, filed on Jan. 21, 2020.

(51) Int. Cl. G01R 33/06; G01R 33/09

(52) U.S. Cl. CPC G01R 33/063; G01R 33/093; G01R 33/098

(57) ABSTRACT

Described herein are devices, systems, and methods for controlling the flow of magnetic flux from one location to another. In some aspects, devices, systems, and methods for improving the sensitivity of magnetic field sensors are provided. In some embodiments, improving magnetic field sensor efficiency comprises modulating the frequency of a magnetic field of interest.

### CROSS-REFERENCE

This application claims the benefit of U.S. Provisional Application Nos. 62/963,877, filed Jan. 21, 2020, which application is incorporated herein by reference in its entirety.

### BACKGROUND

Newly developed technologies for measuring magnetic fields have yielded devices and systems that are small, inherently inexpensive, operable at room temperature, and capable of reasonable sensitivity for magnetic field detection. One example of such technologies is the giant magnetoresistive (GMR) sensor, which can be useful in reading information stored on computer hard drives. However, despite widespread efforts, the sensitivity of even the latest technologies has proven inadequate for applications requiring high sensitivity in detecting magnetic fields, such as is required for clinical diagnostic devices. One specific clinical application in which the sensitivity of current technologies falls short is the monitoring of human heart function, for example, from outside the chest wall.

A major obstacle to achieving magnetic field measurement sensitivities is the effect of low-frequency l/f resistive noise produced by magnetic field sensors, such as GMR and tunneling magnetoresistance (TMR) sensors. In clinical applications, high sensitivity magnetic field detection is critical. For example, the magnetic field produced by the heart's electrical function is approximately one million times less than the Earth's magnetic field. The magnetic fields produced by the heart have low frequencies, frequencies that are in the same frequency range as the relatively strong l/f noise. One proposed solution is to shift the low-frequency cardiac fields to higher frequencies where the noise can be several orders of magnitude less. The basic phenomenon used to shift the frequency of a signal is well known and is used in many applications. When the strength of one sinusoidal signal is modulated by a second sinusoidal frequency, the resulting signal comprises of two sinusoidal signals, one with frequency given by the sum of the two initial frequencies and the other given by the difference of the two initial frequencies. Modulating one signal with another is effectively multiplying the two. Mathematically, multiplying two dissimilar sinusoids results in the sum and difference frequencies.

Microelectromechanical systems (MEMS) devices have been developed to shift the frequency of magnetic fields of interest in the vicinity of a magnetic field sensor, thus moving the signal of a magnetic field of interest from a low frequency where sensor noise may affect sensitivity of detection to a higher frequency where there exists significantly less sensor noise. MEMS devices can modulate the strength of the magnetic field by physically moving or flexing magnetic flux concentrators or flux guides placed within the magnetic field in proximity to the sensor, thereby deflecting or guiding the magnetic field near the sensor and altering the field strength detected by the sensor as a function of time. For example, some MEMS-based magnetic field sensing devices function by driving the outer ends of movable flux concentrator flaps up and down using electrostatics, which causes the inner ends of the flux concentrators to be repetitively moved closer to and then further away from a TMR sensor as the flux concentrators are driven up and down by the electrostatics, thus modulating the magnetic field detected or “seen” by the sensor.

In some cases, MEMS-based magnetic field sensing devices operate by moving a magnetic flux guide close to and parallel to a sensor and then moving the flux guide away from the sensor. When the flux guide is brought near to the sensor, the magnetic flux preferentially travels through the low-resistance flux guide and not the sensor. When the flux guide is moved away from the sensor, the sensor “sees” more magnetic flux. In some cases, only a portion of the flux guide is moved toward and away from the sensor, contacting stationary portions of the flux guide on either side of the sensor when the movable flux guide is brought near to the sensor, thus providing a continuous magnetic flux path when the movable flux guide is moved into contact with the stationary flux guide portions.

Unfortunately, existing methods of modulating a magnetic field seen by a sensor have low efficiency and have not been shown to significantly improve sensor sensitivity. Further, the complexity of fabricating a sensor system that relies on mechanically moving a portion of the magnetic detection apparatus, as is the case in MEMS-based systems, also renders such devices exceedingly difficult to manufacture and draws into question their utility in applications requiring high sensitivity. Therefore, there are needs for improved magnetic field sensors and sensor systems that address these drawbacks.

### REFERENCES IN THE FIELD MAY INCLUDE

Du Q, Hu J, Sun K, Chen D, et al., “High Efficiency Magnetic Flux Modulation Structure for Magnetoresistance Sensor”, IEEE Electron Device Letters 2019; 40(11): 1824-1827.

Duan H, Gupta A, Li Y, Tseng H W, van Dover R B, “Design and Validation of High-Efficiency Chopper for Magnetoresistive Sensors”, IEEE Trans Magn 2012; 48(9): 2461-2466.

Edelstein A S, “Method and apparatus for utilizing magnetic field modulation to increase the operating frequency of sensors”, U.S. Pat. No. 8,222,898.

Edelstein A S, Fischer G A, “Minimizing l/f noise in magnetic sensors using a microelectromechanical system flux concentrator”, J Appl Phys 2002; 91(10): 7795-7797.

Hinshaw W, “Current-sensing Method of GMI Magnetic Field Measurement”, U.S. patent application Ser. No.: 16/708,347; 2019 and WO 2020/167551.

### SUMMARY

Systems, devices, and methods for measuring magnetic fields are provided herein. The embodiments of the disclosure can address at least some of the above limitations and deficiencies.

In various aspects, a system for detecting a magnetic field comprises a magnetic field sensor; and one or more current-driven flux modulators (CDFMs), each CDFM comprising a magnetically soft material; and one or more current sources electrically coupled to the one or more of CDFMs. In some embodiments, a magnetic permeability of the magnetically soft material decreases when electrical current is applied to the CDFM. In some embodiments, a direction of sensitivity of the magnetic field sensor is oriented at an angle of zero relative to a longitudinal axis of the one or more CDFMs defined by a proximal end and a distal end of the CDFMs. In some embodiments, a direction of sensitivity of the magnetic field sensor is oriented at a non-zero angle relative to a longitudinal axis of one or more CDFMs defined by a proximal end and a distal end of the CDFM. In some embodiments, a proximal end of the one or more CDFMs is positioned proximal to the magnetic field sensor. In some embodiments, at least one CDFM of the one or more CDFMs comprises a microwire. In some embodiments, a first current source of the one or more current sources provides a first electrical drive current having a first repetitive electrical drive current pattern. In some embodiments, the first repetitive electrical drive current pattern comprises an oscillatory waveform. In some embodiments, the oscillatory waveform comprises a frequency greater than a frequency of a magnetic field signal of interest. In some embodiments, a second current source of the one or more current sources is configured to provide a second repetitive electrical drive current having a different frequency than a frequency of the first repetitive electrical drive current. In some embodiments, the system is configured to apply the first repetitive electrical drive current to a first CDFM and the second repetitive electrical drive current to a second CDFM, wherein a longitudinal axis of the first CDFM and a longitudinal axis of the second CDFM are oriented at a non-zero angle with respect to one another. In some embodiments, the magnetic field sensor comprises a magnetoresistive sensor. In some embodiments, the magnetoresistive sensor is a giant magnetoresistive sensor or a tunneling magnetoresistive sensor. In some embodiments, the magnetic field sensor comprises a giant magnetoimpedance sensor. In some embodiments, the magnetic field sensor comprises a coil comprising an electrically conductive material and a core comprising a magnetically soft material, wherein the coil is disposed at least partially around the core. In some embodiments, the system is configured to detect the magnetic field based on an electrical current or voltage in the coil.

In various aspects, a device for controlling the flow of magnetic flux from a first location to a second location comprises: an elongate flux modulator comprising a first electrical connection point at a first end of the elongate flux modulator and a second electrical connection point at a second end of the elongate flux modulator, wherein the first and second electrical connection points are couplable to an electrical current source, wherein the elongate flux modulator comprises a magnetically soft material and wherein the magnetically soft material changes magnetic permeability upon the application of an electrical current. In some embodiments, the second location comprises a magnetic field sensor. In some embodiments, the magnetic permeability of the magnetically soft material decreases upon application of the electrical current. In some embodiments, the magnetic permeability of the magnetically soft material increases upon removal of an electrical current applied to the magnetically soft material.

In various aspects, a method of detecting a magnetic field comprises: providing a magnetic field sensor within a magnetic field; providing one or more current-driven flux modulators (CDFMs) proximal to the magnetic field sensor, each CDFM of the one or more CDFMs comprising a magnetically permeable material; applying one or more electrical drive currents to the one or more CDFMs; and detecting the magnetic field with the magnetic field sensor. In some embodiments, applying one or more electrical drive currents changes the magnetic permeability of the one or more CDFMs. In some embodiments, applying the one or more electrical drive currents decreases the magnetic permeability of the one or more CDFMs. In some embodiments, the electrical drive current comprises an oscillatory waveform. In some embodiments, the one or more electrical drive currents comprises an oscillation frequency greater than a frequency of the magnetic field prior to applying the one or more electrical drive currents to the one or more CDFMs. In some embodiments, a proximal end of the one or more CDFMs is positioned proximal to the magnetic field sensor. In some embodiments, the method further comprises filtering a signal obtained by detecting the magnetic field. In some embodiments, the filtering comprises applying a high pass filter to the signal. In some embodiments, the one or more electrical drive currents comprises a plurality of electrical drive currents and wherein a first electrical drive current of the plurality of electrical drive currents comprises a repetitive drive current pattern with a different frequency than a frequency of a second electrical drive current of the plurality of electrical drive currents. In some embodiments, the first electrical drive current is applied to a first CDFM and a second electrical drive current is applied to a second CDFM, wherein a longitudinal axis of the first CDFM and a longitudinal axis of the second CDFM are oriented at a non-zero angle with respect to one another. In some embodiments, the magnetic field sensor comprises a magnetoresistive sensor. In some embodiments, the magnetic field sensor comprises a giant magnetoresistive sensor or a tunneling magnetoresistive sensor. In some embodiments, the magnetic field sensor comprises a giant magnetoimpedance sensor. In some embodiments, the CDFM comprises a microwire. In some embodiments, the magnetic field sensor comprises a coil comprising an electrically conductive material and a core comprising a magnetically soft material, wherein the coil is disposed at least partially around the core. In some embodiments, the method further comprises detecting the magnetic field by detecting an electrical current or voltage in the coil.

Not necessarily all such aspects or advantages are achieved by any particular embodiment. Thus, various embodiments may be carried out in a manner that achieves or optimizes one advantage or group of advantages taught herein without necessarily achieving other aspects or advantages as may also be taught or suggested herein.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the present disclosure are set forth with particularity in the appended claims. A better understanding of the features and advantages of the present disclosure will be obtained by reference to the following detailed description that sets forth illustrative embodiments, in which the principles of the present disclosure are utilized, and the accompanying drawings of which:

FIG. 1 shows a schematic of a magnetic field sensor system comprising a current-driven flux modulator (CDFM), in accordance with embodiments.

FIGS. 2A and 2B show graphs of an example of a magnetic field measured by a sensor of a magnetic field sensor system (FIG. 2B) resulting from a current driven in the CDFM (FIG. 2A).

FIG. 3 shows a schematic of magnetic field sensor system comprising a CDFM, in accordance with embodiments.

FIG. 4 shows a schematic of a magnetic field sensor system comprising a CDFM, in accordance with embodiments.

FIG. 5 shows a schematic of a magnetic field sensor system comprising a CDFM, in accordance with embodiments.

FIGS. 6A-6C show graphs of an example of a magnetic field measured by a sensor of a magnetic field sensor system (FIG. 6C), which can result from a first current driven in a first CDFM of the magnetic field sensor system (FIG. 6A) and a second current driven in a second CDFM of the magnetic field sensor system (FIG. 6B), in accordance with embodiments.

FIG. 7 shows a schematic of a magnetic field sensor system, in accordance with embodiments.

FIGS. 8A-8C show graphs of an example of a magnetic field measured by a sensor of a magnetic field sensor system comprising a CDFM (FIG. 8A), which can result from a first current driven in a first CDFM of the magnetic field sensor system (FIG. 8B) and a second current driven in a second CDFM of the magnetic field sensor system (FIG. 8C), in accordance with embodiments.

FIG. 9 shows an illustration of an example of a magnetic field sensor system comprising a CDFM, in accordance with embodiments.

FIG. 10 shows an illustration of a coaxial cable comprising a CDFM, in accordance with embodiments.

### DETAILED DESCRIPTION

Described herein are devices, systems, and methods for the detection of magnetic fields and for obtaining improved sensitivity in the measurement or detection magnetic fields. A major challenge to existing magnetic field sensors is that they can produce far more noise in the low-frequency ranges than in high frequencies. Much of this low-frequency noise can be low-frequency l/f noise, an electromagnetic noise primarily affecting the low end of the frequency range and occurring in most electronic devices, sometimes referred to as “pink noise.” The l/f noise can present a major challenge in applications requiring sensitive measurement of magnetic signals in a low frequency band, such as biological signals (e.g., magnetic fields created during cardiac function).

As presented herein, the effects of electromagnetic noise (e.g., l/f noise) can be greatly reduced and the sensitivity of a magnetic field sensor system (e.g., a magnetic field detection system) greatly increased by modulating (e.g., shifting) the apparent frequency of a magnetic field, as detected (or “seen”) by a magnetic sensor. In particular, the sensitivity of a magnetic field sensor can be improved by modulating an electrical current in a magnetically conductive material (e.g., a magnetic flux conductor, such as a magnetic flux guide) positioned in the vicinity of the sensor. Modulation of an electrical current in a magnetically conductive material positioned in the vicinity of a magnetic field sensor can modulate the amplitude of the magnetic field near the magnetic field sensor, thus altering the frequency of the field of interest, as detected (or “seen”) by the magnetic field sensor and effectively shifting the frequency of a magnetic field signal of interest (e.g., from low frequency to a higher frequency) from the perspective of the magnetic field sensor. Without wishing to be bound by theory, this can occur as the result of temporal modulation of the magnetic permeability of the magnetically conductive material through which the temporally modulated current flows, which can directly affect the degree to which the magnetically conductive material allows or disallows magnetic flux through the material (e.g., and through or across the magnetic field sensor).

By modulating a current within the magnetically conductive material, it is not necessary to physically move a portion of the magnetic field sensor system (e.g., using mechanically driven modulators) to shift the frequency of the field, in many embodiments. This can simplify the design and manufacture of the system. For example, in many cases, no additional space or clearance is needed for physical oscillation of components. In contrast to existing (e.g., mechanically driven modulator) systems, mechanical fatigue of components may not be a concern in the systems presented herein. Furthermore, fabrication and assembly of the components of a current-mediated magnetic field modulator (e.g., as described herein) can be simpler than in systems requiring mechanically-driven modulators, such as MEMS-based systems. Mechanical resonances that may arise from mechanically driven modulators may not be a concern in systems that rely on current-mediated magnetic field modulation, as described herein. Importantly, current-mediated magnetic field modulation can be used to produce a wider range of magnetic frequency shifts and can shift magnetic fields to higher frequencies than existing technologies, such as those relying on mechanically-driven modulators. Current-mediated magnetic field modulation can also be tuned and adjusted more easily than systems reliant on mechanically-driven modulators. For example, a new input current pattern can easily be implemented in current-mediated magnetic field modulation systems to change the frequency shift applied to the magnetic field of interest, allowing facile adjustments between or during magnetic field measurements, for example, to adjust for dynamic changes in environmental noise.

After a magnetic field (e.g., a modulated magnetic field) is detected, for example by a magnetic field sensor, the detected magnetic field signals can be shifted back to their original frequencies. In many cases, the detected magnetic field signals can be shifted back to their original frequencies in silico, for example, using a computer processor and computer program stored thereupon to process the detected magnetic field signal. In some cases, a detected magnetic field signal can be filtered, e.g., via incorporation of solid state electronic architecture into the magnetic field sensor system and/or software-based computer signal processing.

### Magnetic Field Sensor Systems

A magnetic field sensor system can comprise a sensor, for instance a magnetoresistive sensor capable of detecting magnetic fields (e.g., a magnetic field sensor). In some cases, a magnetoresistive sensor can be a tunnel magnetoresistive sensor (TMR). In some cases, a magnetoresistive sensor can be a giant magnetoresistive (GMR) sensor. In some embodiments, a sensor of a magnetic field sensor system can be not a magnetoresistive sensor. For instance, a sensor of a magnetic field sensor system can be a giant magnetoimpedance (GMI) sensor. In some embodiments, additional or alternative sensor technologies can be used in magnetic field sensor systems presented herein.

A magnetic field sensor system can comprise one or more magnetic flux paths. A flux path can comprise one or more of a current-driven flux modulator (CDFM), a flux guide, or a flux concentrator. In many cases, a CDFM can be used to modulate a magnetic flux detected by a sensor of a magnetic field sensor system (e.g., by driving a temporally dynamic current pattern through the CDFM, for instance, to vary magnetic permeability in the CDFM). A magnetic field sensor system comprising a CDFM can achieve higher magnetic field modulation efficiency than existing technologies (e.g., by modulating a magnetic flux of a magnetic field signal of interest at a high frequency, which can separate the signal of interest from environmental magnetic noise). For example, a magnetic field sensor system comprising one or more CDFMs can have a much higher ratio of magnetic flux conduction to non-conduction compared to prior art methods. In many cases, positioning a magnetic flux path in close proximity to a magnetic field sensor can aid in guiding or concentrating magnetic fields of interest in one or more desired directions. A magnetic flux path can be oriented such that a magnetic field is guided through the magnetic flux path and toward a magnetic field sensor of a magnetic field sensor system. For instance, a magnetic flux path comprising a microwire can be oriented such that one end of the microwire is pointed toward the magnetic field sensor. In some cases, a magnetic flux path comprises a microwire. A magnetic flux path can comprise a magnetically soft material. In many cases, a magnetic flux path has a high magnetic permeability. In some cases, a magnetic flux path can have a magnetic permeability of from 0.00001 Henries/meter (H/m) to 1.5 H/m. In some embodiments, a material comprising at least a portion of a magnetic flux path can have a magnetic permeability of from 0.01 H/m to 1.5 H/m. In some embodiments, a material comprising at least a portion of a magnetic flux path can have a magnetic permeability of from 0.01 H/m to 0.05 H/m, 0.01 H/m to 0.1 H/m, 0.01 H/m to 0.25 H/m, 0.01 H/m to 0.5 H/m, 0.01 H/m to 0.75 H/m, 0.01 H/m to 1 H/m, 0.01 H/m to 1.25 H/m, 0.01 H/m to 1.5 H/m, 0.05 H/m to 0.1 H/m, 0.05 H/m to 0.25 H/m, 0.05 H/m to 0.5 H/m, 0.05 H/m to 0.75 H/m, 0.05 H/m to 1 H/m, 0.05 H/m to 1.25 H/m, 0.05 H/m to 1.5 H/m, 0.1 H/m to 0.25 H/m, 0.1 H/m to 0.5 H/m, 0.1 H/m to 0.75 H/m, 0.1 H/m to 1 H/m, 0.1 H/m to 1.25 H/m, 0.1 H/m to 1.5 H/m, 0.25 H/m to 0.5 H/m, 0.25 H/m to 0.75 H/m, 0.25 H/m to 1 H/m, 0.25 H/m to 1.25 H/m, 0.25 H/m to 1.5 H/m, 0.5 H/m to 0.75 H/m, 0.5 H/m to 1 H/m, 0.5 H/m to 1.25 H/m, 0.5 H/m to 1.5 H/m, 0.75 H/m to 1 H/m, 0.75 H/m to 1.25 H/m, 0.75 H/m to 1.5 H/m, 1 H/m to 1.25 H/m, 1 H/m to 1.5 H/m, or 1.25 H/m to 1.5 H/m. In some embodiments, a material comprising at least a portion of a magnetic flux path can have a magnetic permeability of from 0.01 H/m, 0.05 H/m, 0.1 H/m, 0.25 H/m, 0.5 H/m, 0.75 H/m, 1 H/m, 1.25 H/m, or 1.5 H/m. In some embodiments, a material comprising at least a portion of a magnetic flux path can have a magnetic permeability of from at least 0.01 H/m, 0.05 H/m, 0.1 H/m, 0.25 H/m, 0.5 H/m, 0.75 H/m, 1 H/m, 1.25 H/m, or 1.5 H/m. In some embodiments, a material comprising at least a portion of a magnetic flux path can have a magnetic permeability of from at most 0.01 H/m, 0.05 H/m, 0.1 H/m, 0.25 H/m, 0.5 H/m, 0.75 H/m, 1 H/m, 1.25 H/m, or 1.5 H/m. A magnetically soft material of a magnetic flux path (e.g., a CDFM) can be an alloy. For instance, a portion of a magnetic flux path (e.g., a CDFM) can comprise one or more magnetically soft alloys selected from iron-silicon alloys, cobalt-iron alloys, nickel-iron alloys, and soft ferrites. In many cases, a portion of a magnetic flux path can also be electrically conductive. In many cases, a portion of a magnetic flux path can comprise a magnetically soft material that experiences a change in magnetic permeability when a current is passed through the material. In some cases, a portion of a magnetic flux path can comprise cobalt, nickel, iron, ferrite, steel, molybdenum, zinc, Metglas Permalloy, MuMETAL®, NANOPERM®, or a combination thereof. A magnetic field sensor system can comprise a plurality of magnetic flux paths. For instance, a magnetic field sensor can comprise 1, 2, 3, 4, 5, 6, 7, 8, 9, 10, 11, 12, from 13 to 20, from 20 to 30, from 30 to 40, from 40 to 50, or more than 50 magnetic flux paths. A magnetic flux path of a magnetic field sensor system, such as one or more CDFM(s) of the magnetic field sensor system can be constructed on a printed circuit board or other base with strip-lines or by using alternative techniques known in the art.

A CDFM can comprise a microwire. In many cases, a CDFM can comprise a magnetically soft material that experiences a change in magnetic permeability when a current is passed through the material. In some embodiments, a CDFM can comprise a material having high permeability. High permeability can aid in a material's ability to guide magnetic flux toward a sensor. In some embodiments, a material useful in a CDFM can have a permeability of from 0.00001 H/m to 1.5 H/m. In some embodiments, a material useful in a CDFM can have a permeability of from 0.01 H/m to 0.1 H/m, 0.01 H/m to 0.25 H/m, 0.01 H/m to 0.5 H/m, 0.01 H/m to 0.75 H/m, 0.01 H/m to 1.0 H/m, 0.01 H/m to 1.25 H/m, 0.01 H/m to 1.5 H/m, 0.1 H/m to 0.5 H/m, 0.1 H/m to 0.75 H/m, 0.1 H/m to 1.0 H/m, 0.1 H/m to 1.25 H/m, 0.1 H/m to 1.5 H/m, 0.5 H/m to 1.0 H/m, 0.5 H/m to 1.25 H/m, 0.5 H/m to 1.5 H/m, 0.75 H/m to 1.25 H/m, 0.75 H/m to 1.5 H/m, or 1.0 H/m to 1.5 H/m. In some embodiments, a material useful in a CDFM can have a permeability of from 0.00001 H/m, 0.0001 H/m, 0.001 H/m, 0.01 H/m, 0.1 H/m, or 1 H/m. In some embodiments, a material useful in a CDFM can have a permeability of from at least 0.00001 H/m, 0.0001 H/m, 0.001 H/m, 0.01 H/m, 0.1 H/m, or 1 H/m. In some embodiments, a material useful in a CDFM can have a permeability of from at most 0.00001 H/m, 0.0001 H/m, 0.001 H/m, 0.01 H/m, 0.1 H/m, or 1 H/m.

In some cases, a CDFM can comprise cobalt, nickel, iron, ferrite, steel, molybdenum, zinc, Metglas®, Permalloy, MuMETAL®, NANOPERM®, or a combination thereof. A CDFM can comprise a magnetically soft material. In many cases, a magnetically soft material of a CDFM can be an alloy. For instance, a CDFM can comprise one or more magnetically soft alloys selected from iron-silicon alloys, cobalt-iron alloys, nickel-iron alloys, and soft ferrites. In many cases, a CDFM can also be electrically conductive. In some cases, a CDFM can comprise a non-conductive material having high magnetic permeability, such as ferrite. For example, a CDFM can comprise a non-conductive material with high magnetic permeability, e.g., in order to electrically isolate the current-modulated portion(s) of the CDFM from a sensor of the magnetic field sensor system. In some cases, such non-conductive but highly permeable materials can aid in design of the magnetic field sensor system, as a non-conductive end cap on the CDFM that allows magnetic flux to pass through can allow the CDFM to be positioned extremely close to the sensor without allowing an electrically conductive bridge. Minimizing the distance between the CDFM and the sensor can aid in optimizing transmission of a magnetic field of interest to the sensor.

The physical arrangement of one or more components of a magnetic field sensor system can affect the sensitivity of system for detecting a magnetic field of interest. The positioning of one or more CDFMs relative to a sensor and a magnetic field of interest can be leveraged to increase the sensitivity of the system, for example, as described in the system configurations discussed below. In many embodiments, a device or system disclosed herein can control the flow of magnetic flux from a first location to a second location, for example, from a distal end of a CDFM to a second location, such as a proximal end of the CDFM or the location of a sensor. In some cases, a first (e.g., axially aligned) CDFM 12 can be positioned “upstream” in the magnetic field relative to sensor 11, e.g., wherein a magnetic field passes through the CDFM before passing through the sensor. In some cases, a second (e.g., axially aligned) CDFM 13 can be positioned “downstream” in the magnetic field relative to sensor 11 (e.g., wherein a magnetic field passes through the CDFM after it passes through the sensor), for example, to steady and further establish the magnetic flux through the sensor (e.g., when no current is driven through the CDFM). In some cases, for instance in “axial” configurations or “non-axial” configurations, a first end (e.g., proximal end) of a CDFM can be oriented proximal to a sensor relative to a second end (e.g., distal end) of the CDFM. In some cases, a second end (e.g., a distal end) of a CDFM can be oriented distal to a sensor relative to a first end (e.g., proximal end) the CDFM. While several examples and figures described herein illustrate systems having two or four CDFMs, it is contemplated that a system can comprise any number of CDFMs (e.g., with any number of CDFMs positioned in-line with one another or with one or more of the CDFMs oriented parallel to or at an angle to one or more of the other CDFMs). In some cases, a magnetic field sensor system can comprise 1, 2, 3, 4, 5, 6, 7, 8, 9, 10, 10-15, 15-20, 20-30, 30-50, or more than 50 CDFMs. It may be beneficial for the CDFM to consist of an even number (e.g., two or four) microwires with the current being driven in opposite directions at a given time in any two CDFM microwires in close proximity to one another. In some cases, such configurations can minimize components of magnetic field(s) generated by the microwires.

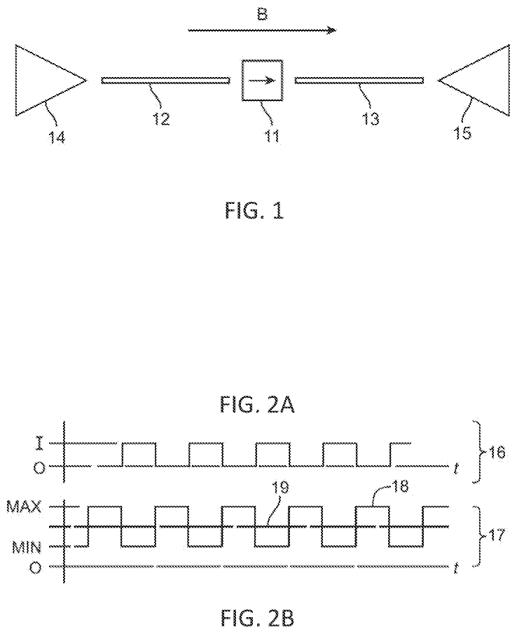

A magnetic field sensor system having an “axial” configuration in accordance with various embodiments is shown in FIG. 1. A magnetic field sensor system can comprise a CDFM (e.g., CDFM 12 or CDFM 13) positioned in proximity to a magnetic field sensor 11 within a magnetic field. Magnetic field B is indicated in FIG. 1 with an arrow schematically indicating directionality of magnetic flux in a portion of the field detectable by sensor 11. In some cases, a magnetic field sensor 11 of a magnetic field sensor system can be oriented within magnetic field B such that the direction of sensitivity of the sensor (indicated in FIG. 1 by the arrow on sensor 11) is aligned with the expected direction of a magnetic field of interest. In some cases, one or more CDFMs (e.g., comprising a magnetically permeable and electrically conductive material) can be aligned with the direction of the sensor 11 and/or the magnetic field B. A magnetic field sensor system can comprise a plurality of CDFMs (e.g., CDFM 12 and CDFM 13). CDFM 12 and CDFM 13, which can each comprise magnetically permeable and electrically conductive material, can be elongate in shape and can be oriented such that a long axis of each CDFM is in line with (e.g., “axially” aligned with) the direction of sensitivity of the magnetic field sensor 11, e.g., as shown in FIG. 1. Such axial configurations can be useful in guiding magnetic flux to the sensor through the CDFM(s) (e.g., when no current flows through the CDFM(s)). A magnetic field sensor (e.g., sensor 11) may, in some cases, comprise any one of the magnetic field sensors described in U.S. Patent Publication No. US 2020/0256930 A1 and PCT Patent Publication No. WO2020167551A1, which are incorporated herein in its entirety and for all purposes.

A magnetic field sensor system can comprise one or more current source(s) and electrically conductive leads electrically joining the one or more current source(s) to one or more of the CDFMs of the magnetic field sensor system. The current source and electrical connections (e.g., to CDFM 12 and CDFM 13) are not shown in FIG. 1. A CDFM (e.g., CDFM 12 and/or CDFM 13) can be connected to a positive terminal of a current source at a first electrical connection point (e.g., at a first end) of the CDFM and to a negative terminal of the current source at a second electrical connection point (e.g., at a second end) of the CDFM, for instance so that an electrical current can be driven through the CDFM, e.g., to alter the magnetic permeability of the CDFM of the magnetic field sensor system. In some cases, a positive terminal of a current source can be connected to a proximal end (e.g., a first end) of a CDFM. In some cases, a negative terminal (e.g., a second end) of a current source can be connected a distal end of a CDFM. In some cases, a positive terminal of a current source can be connected to a distal end of a CDFM. In some cases, a negative terminal of a current source can be connected to a proximal end of a CDFM. Briefly, the magnetic permeability of certain materials (e.g., materials comprising a magnetically permeable alloy, such as Metglas Permalloy, MuMETAL®, and NANOPERM®,) can be decreased by applying a current to the material, which can affect (e.g., decrease) the amount of magnetic flux of a magnetic field that a component comprising the material can conduct. For example, applying an electrical current (e.g., an electrical drive current) to a CDFM comprising a magnetically soft material as described herein can decrease the magnetic permeability of the magnetically soft material of the CDFM. In some cases, increasing the magnitude of an electrical current (e.g., an electrical drive current) to a CDFM comprising a magnetically soft material as described herein can decrease the magnetic permeability of the magnetically soft material of the CDFM. Decreasing the magnetic permeability of a CDFM of a magnetic field sensor system can decrease the amount of magnetic flux of a magnetic field of interest reaching a sensor of the system (e.g., and decreasing the apparent magnitude of the magnetic flux “seen” by the sensor). A current driven through a CDFM can cause the magnetic permeability of the CDFM to decrease proportionally. In some cases, removing (or otherwise interrupting) an electrical current (e.g., an electrical drive current) to a CDFM comprising a magnetically soft material as described herein can cause the magnetic permeability of the magnetically soft material of the CDFM to increase. In some cases, decreasing an electrical current (e.g., an electrical drive current) to a CDFM comprising a magnetically soft material as described herein can cause the magnetic permeability of the magnetically soft material of the CDFM to increase. When modulated at a high frequency, the current driven through a CDFM can subsequently result in the sensor “seeing” a high frequency variation in the magnitude of the magnetic field. A more complete discussion of the process of altering the magnetic permeability of a magnetic field sensor system component (e.g., a CDFM) can be found in U.S. Patent Publication No. US 2020/0256930 A1 and PCT Patent Publication No. WO2020167551A1, which are incorporated herein in its entirety and for all purposes.

In some cases, a current source can be used or programmed to drive one or more CDFMs with an electrical current having a specific pattern. For instance, a current source can drive a CDFM with a current, or “drive-current” (e.g., an electrical drive current), e.g., having a constant amplitude or a temporally modulated (e.g., sinusoidal) amplitude. In some cases, an electrical drive current can be repetitive, for example, wherein all or a portion of the waveform repeats over time. In some cases, a drive current having a constant amplitude (e.g., by applying a constant voltage to a first and second electrical connection of a CDFM) can be repeatedly applied and removed from a CDFM, for example, in order to drive the CDFM with a current having a square wave pattern. In some cases, a drive current may reverse direction over time (e.g., repeatedly), for instance, as is the case in some sinusoidal or square wave drive currents. Plot 16 of FIG. 2A shows a possible square wave pattern of a drive current applied to the CDFMs as a function of time, wherein the applied drive current alternates between zero and a maximum (indicated by the letter I). Many other current patterns can be used to drive current within a CDFM. For instance, an oscillatory waveform (e.g., sinusoidal and/or sawtooth alternating current patterns) may be used to drive current within a CDFM. In some cases, a first current source can be used to provide a first (e.g., repetitive) electrical drive current to a first CDFM and a second current source can bused to provide a second (e.g., repetitive) electrical drive current to a second CDFM, for example, wherein the first and second electrical drive currents comprise waveforms having different frequencies. In general, electrical drive current patterns having a regular frequency can be useful and convenient for inducing a high frequency signal in a magnetic field proximal to a magnetic field sensor 11 (e.g., wherein the apparent amplitude of the magnetic flux is modulated such that it is “seen” by the sensor as varying with a high frequency). In many cases, an electrical drive current pattern (or at least a portion of a waveform thereof) can have a frequency greater than a frequency of a magnetic field signal of interest (e.g., wherein the magnetic field signal of interest comprises a portion of a magnetic field in which a CDFM and/or magnetic field sensor is positioned). In some embodiments, the signal-to-noise ratio for a magnetic field sensor system (e.g., a CDFM system) comprising a magnetic field sensor, for example as disclosed herein, can be improved by (and sensitivity increased by) two to three orders of magnitude when the frequency of a magnetic field is shifted by 2-3 kilohertz (kHz). For example, a magnetic sensor may detect a magnetic field of interest as having a frequency of from 1-5 hertz (Hz) prior to magnetic field modulation (e.g., magnetic flux modulation) and, after application of magnetic field modulation (e.g., using a magnetic field sensor system comprising one or more current driven CDFMs), the magnetic field sensor may detect the magnetic field of interest as having a frequency of 2-3 kHz (e.g., prior to detection), for example, if the CDFMs are driven with a current pattern having a repeating period of 2-3 kHz. In some cases, the frequency of a magnetic field (e.g., a magnetic field of interest) can be shifted (e.g., using a magnetic field sensor system described herein) by 0.001 kHz to 1 GHz or higher. In some embodiments, a frequency of a magnetic field can be increased by 0.001 kHz to 100,000 kHz. In some embodiments, a frequency of a magnetic field can be increased by 0.001 kHz to 0.01 kHz, 0.001 kHz to 0.1 kHz, 0.001 kHz to 1 kHz, 0.001 kHz to 5 kHz, 0.001 kHz to 10 kHz, 0.001 kHz to 50 kHz, 0.001 kHz to 100 kHz, 0.001 kHz to 500 kHz, 0.001 kHz to 1,000 kHz, 0.001 kHz to 10,000 kHz, 0.001 kHz to 100,000 kHz, 0.01 kHz to 0.1 kHz, 0.01 kHz to 1 kHz, 0.01 kHz to 5 kHz, 0.01 kHz to 10 kHz, 0.01 kHz to 50 kHz, 0.01 kHz to 100 kHz, 0.01 kHz to 500 kHz, 0.01 kHz to 1,000 kHz, 0.01 kHz to 10,000 kHz, 0.01 kHz to 100,000 kHz, 0.1 kHz to 1 kHz, 0.1 kHz to 5 kHz, 0.1 kHz to 10 kHz, 0.1 kHz to 50 kHz, 0.1 kHz to 100 kHz, 0.1 kHz to 500 kHz, 0.1 kHz to 1,000 kHz, 0.1 kHz to 10,000 kHz, 0.1 kHz to 100,000 kHz, 1 kHz to 5 kHz, 1 kHz to 10 kHz, 1 kHz to 50 kHz, 1 kHz to 100 kHz, 1 kHz to 500 kHz, 1 kHz to 1,000 kHz, 1 kHz to 10,000 kHz, 1 kHz to 100,000 kHz, 5 kHz to 10 kHz, 5 kHz to 50 kHz, 5 kHz to 100 kHz, 5 kHz to 500 kHz, 5 kHz to 1,000 kHz, 5 kHz to 10,000 kHz, 5 kHz to 100,000 kHz, 10 kHz to 50 kHz, 10 kHz to 100 kHz, 10 kHz to 500 kHz, 10 kHz to 1,000 kHz, 10 kHz to 10,000 kHz, 10 kHz to 100,000 kHz, 50 kHz to 100 kHz, 50 kHz to 500 kHz, 50 kHz to 1,000 kHz, 50 kHz to 10,000 kHz, 50 kHz to 100,000 kHz, 100 kHz to 500 kHz, 100 kHz to 1,000 kHz, 100 kHz to 10,000 kHz, 100 kHz to 100,000 kHz, 500 kHz to 1,000 kHz, 500 kHz to 10,000 kHz, 500 kHz to 100,000 kHz, 1,000 kHz to 10,000 kHz, 1,000 kHz to 100,000 kHz, or 10,000 kHz to 100,000 kHz. In some embodiments, a frequency of a magnetic field can be increased by 0.001 kHz, 0.01 kHz, 0.1 kHz, 1 kHz, 5 kHz, 10 kHz, 50 kHz, 100 kHz, 500 kHz, 1,000 kHz, 10,000 kHz, or 100,000 kHz. In some embodiments, a frequency of a magnetic field can be increased by at least 0.001 kHz, 0.01 kHz, 0.1 kHz, 1 kHz, 5 kHz, 10 kHz, 50 kHz, 100 kHz, 500 kHz, 1,000 kHz, 10,000 kHz, 100,000 kHz. In some embodiments, a frequency of a magnetic field can be increased by at most 0.001 kHz, 0.01 kHz, 0.1 kHz, 1 kHz, 5 kHz, 10 kHz, 50 kHz, 100 kHz, 500 kHz, 1,000 kHz, 10,000 kHz, or 100,000 kHz.

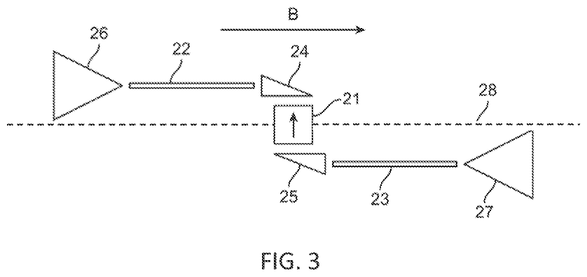

Plot 17 of FIG. 2B shows a time dependence of the magnetic field seen by magnetic field sensor 11 of a magnetic field sensor system (e.g., systems having configurations shown in FIG. 1 and/or FIG. 3) for an (e.g., constant) applied magnetic field (e.g., magnetic field of interest B, shown in FIG. 1). In plot 17, “MIN” indicates the minimum field seen by the sensor 11. In many cases, the minimum detected field value may not be zero, for example, because magnetic field sensor 11 may still see the applied field even when the CDFMs are not conducting flux to the sensor. In plot 17, “MAX” indicates the maximum field seen by the sensor 11. In some cases, the maximum field strength may be detected by the sensor 11 when the drive current is off (e.g., amplitude equal to zero), for example, wherein the CDFMs may have maximum permeability and may be conducting flux to the sensor most efficiently. By carefully modulating the strength of the drive-current to the CDFMs, the corresponding resulting modulated field seen by the sensor can be made sinusoidal rather than a square wave as shown by plot 17. Other field strength patterns can be produced.

It can be seen from plot 17 that the aggregate magnetic field “seen” by sensor 11 may have two components, one alternating, or AC, and the other static, or DC. The trace 17 shows five or six cycles of a square wave, or AC component, indicated by 18. The AC component is added to a DC component indicated by 19.

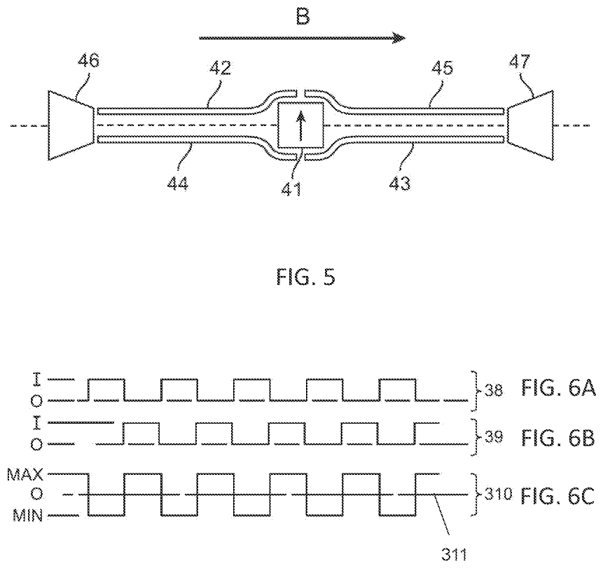

A magnetic field sensor system can comprise one or more flux concentrators. In some cases, a magnetic field sensor system can comprise a plurality of flux concentrators. Flux concentrators can aid in increasing the flux observed by a sensor of a magnetic field sensor system (e.g., as shown in FIG. 1 (elements 14 and 15), FIG. 3 (e.g., elements 26, and 27), and FIG. 5 (e.g., elements 46 and 47). FIG. 1 shows a possible arrangement of flux concentrator 14 and flux concentrator 15. Flux concentrators may comprise magnetically soft alloys, such as Metglas®. One or more materials comprising a flux concentrator can have high permeability. In some cases, a flux concentrator can comprise one or more materials that are electrically non-conductive but with high permeability, such as ferrite. Non-conductive materials may be useful in some designs since it can be beneficial to electrically isolate CDFM microwires from magnetic field sensor 11. In many cases, it can be advantageous for gaps and interruptions in the flux path to be as short as possible, e.g., to improve conduction of magnetic flux to and/or from sensor 11. Flux concentrators (FCs) can be shaped and/or arranged (e.g., within a magnetic field B and/or relative to other components of a magnetic field sensor system, such as a sensor or CDFM) to increase the strength of the field seen by a sensor.

A magnetic field sensor system can comprise one or more flux guides (e.g., flux guide 24 or flux guide 25, as shown in FIG. 3). A flux guide can comprise a magnetically permeable material, for example, a material having high magnetic permeability (e.g., ferrite, Metglas® or other high permeability alloys). Flux guides (FGs) can comprise a magnetically soft alloy. In some cases, a flux guide can increase the strength of the field “seen” by a sensor and/or guide magnetic flux toward or around other components such as a sensor or CDFM, e.g., by shaping the flux guide and/or positioning it relative to the sensor, a CDFM, and/or the magnetic field B. In some cases, a flux guide, or a portion thereof, does not conduct electrical current. In some cases, a flux guide can be used to electrically separate a CDFM from a sensor of a magnetic field sensor system. In some cases, a flux guide or portion thereof can conduct electrical current. In some cases, including a flux guide in a magnetic field sensor system (e.g., in line with a flux modulator such as a CDFM, as shown in FIG. 3, and/or in line with a magnetic field sensor and/or a flux concentrator) can improve flux linkage between two or more components of the magnetic field sensor system. This can improve the efficiency with which magnetic flux is conveyed toward a sensor for detection, which can aid in improving sensitivity of magnetic field measurements. It can be advantageous to position the CDFM(s) of a magnetic field sensor system in close physical proximity to the sensor(s) of the magnetic field sensor system, for example, to provide close magnetic connection between the CDFM(s) and the sensor(s).

It can be advantageous to select and position (e.g., place or orient relative to other components) the components of a magnetic field sensor system to minimize any potential impact of un-modulated magnetic flux (e.g., magnetic field signals other than those of interest, for example, resulting from environmental sources). For example, a magnetic field sensor system comprising a GMI type sensor can be assembled using a shorter GMI microwire than usual to limit the impact of un-modulated magnetic flux. Electromagnetic shielding can also be selectively applied to a magnetic field sensor in order to reduce the impact of environmental and other un-modulated magnetic fields on the sensor's measurements. In some cases, the impact of un-modulated magnetic fields on sensor readings can be evaluated by determining detectable magnetic field strengths when the CDFM(s) of a magnetic field sensor system are not conducting flux (e.g., when permeability in the CDFM(s) is low). Such a technique can be useful in evaluating modulation efficiency and in designing magnetic field sensor system composition and spatial layout, as it can provide a baseline magnetic field reading for comparison and/or optimization.

In some cases, it can be advantageous to electrically couple the drive-current of two or more CDFMs. In some embodiments, two or more CDFMs can be electrically coupled across a magnetic field sensor, for example, to simplify delivery of current to the CDFMs and/or to synchronize current in a plurality of CDFMs. To reduce the chance of generating a magnetic field detectable to the magnetic field sensor, an electrically conductive material that does not produce a magnetic field that can be seen by the sensor when driven with current (e.g., copper tubing, in which very little magnetic field is produced, even when it is conducting current.) can be used to connect two or more CDFMs across the sensor. It can also be advantageous to electrically insulate the CDFM(s) from the sensor(s) (and, in some cases, from one another). In some cases, for example, wherein the sensor comprises a microwire (e.g., a GMI sensor), the microwires can be placed end-to-end (or side-by-side) with a thin electrically insulating film between them.

In many cases, a magnetic field sensor (e.g., sensor 11) can detect at least a portion of an applied magnetic field B, for instance, regardless of the action of the CDFMs. In some cases, CDFMs may still conduct some flux even when the drive-current is flowing (e.g., when magnetic permeability in the CDFM is low). In some cases, the magnetic field sensor may see a portion of the magnetic field B that is not modified (e.g., un-modulated) by the action of the CDFMs. However, when the drive-currents are not flowing, the CDFMs and, optionally, flux concentrators of the system can allow more magnetic flux to reach the magnetic field sensor. Thus, in many cases, a magnetic field sensor of a magnetic field sensor system can detect a (e.g., un-modulated) magnetic field present while a drive-current is applied to a CDFM in addition to a (e.g., modulated) magnetic field conducted to the sensor by the CDFM(s) and optional flux guide(s) and flux concentrator(s) at the same time. Accordingly, the aggregate magnetic field signal detected by a magnetic field sensor can comprise both a low-frequency (e.g., un-modulated) magnetic field signal component and high-frequency (e.g., modulated) magnetic field signal component. Using the methods, systems, and devices described herein, a magnetic field signal of interest (e.g., which may be modulated to a high frequency using CDFMs) can be separated from low-frequency noise generated by environmental sources, such as the magnetic field sensor itself, which remains at low frequencies during operation of the magnetic field sensor system.

An aggregate magnetic field signal (e.g., comprising a low-frequency component and/or a high-frequency component) can be filtered. For example, an aggregate magnetic field signal can be filtered either before the detected magnetic field signal is returned from a sensor to a computer or display for user presentation or computer memory storage (e.g., using solid state electrical filtering architectures) or after the detected magnetic field signal is returned to a computer or display for user presentation or computer memory storage (e.g., using post-processing software). In some cases, a high-pass filter (e.g., comprising solid state electrical components or software based signal filtering) can be used to filter (e.g., reduce or eliminate) low-frequency noise from the magnetic signal. In some cases, digital filtering (for example, using computer software) can be applied after a magnetic signal has been Fourier transformed to a frequency-domain signal. In some cases, digital filtering can be applied to the signal in the time domain.

High-frequency components of a detected magnetic field signal can be ‘de-modulated’ in several ways. For instance, a high-frequency magnetic field signal can be rectified and filtered (e.g., using a low-pass filter. Because the exact frequency and phase of the modulation of the magnetic field signal of interest is known (e.g., because the frequency modulation can be based on the frequency modulation of the drive current applied to the CDFMs), phase-coherent de-modulation techniques may be used to isolate magnetic field signal(s) of interest modulated prior to detection by current modulation of CDFMs in the system used to acquire the magnetic field signal(s). Other methods of obtaining the desired (e.g., frequency based) information from the signal may be used. Examples of such signal processing methods can incorporate techniques known in the literature. It is also contemplated that a first magnetic field signal of interest can be separated from a second magnetic field signal of interest (e.g., where the second magnetic field signal of interest is in a direction perpendicular to that of the first magnetic field signal of interest) by modulating two sets of CDFMs (e.g., wherein the first set of CDFMs is configured similar to the system shown in FIG.3 and the second set of CDFMs is oriented perpendicularly to the first set of CDFMs) using drive currents having different frequencies in each of the two sets of CDFMs.

### Crossed-Sensor Configuration

A mentioned above, certain architectures of magnetic field sensor systems can be limited in that the magnetic field sensor may report or “see” a portion of an applied magnetic field B even when the CDFMs are not conducting magnetic flux (e.g., when current is driven through the CDFMs to reduce magnetic permeability of the CDFMs). As show in FIG. 3, the efficiency of the sensor configuration may be improved by positioning magnetic field sensor 21 such that the direction of sensitivity of the magnetic field sensor is at right angles to one or more CDFMs (e.g., CDFM 22 and CDFM 23). With such a configuration, magnetic field sensor 21 “sees” the field in the vertical direction as drawn but does not see the field in the horizontal-direction. The field component in the vertical direction will not be modulated by the CDFMs and thus can be removed easily by the subsequent signal processing. A magnetic field component in the horizontal direction (e.g., indicated as field B), however may be modulated, e.g., as described herein. This configuration can significantly reduce the strength of the MIN field strength as shown in FIG. 2B and thus can improve the efficiency of the magnetic field sensor system assembly.

Flux guides such as flux guide 24 and flux guide 25 can be added to improve the flux linkage between the CDFMs and the sensor. Optional flux concentrators (e.g., flux concentrator 26 and flux concentrator 27) are also shown. CDFM(s) of the system (e.g., CDFM 22 and CDFM 23) can be oriented (e.g., bent, tilted, or turned) in toward center-line 28 in order to reduce the net vertical-component of the field reported by the sensor.

A signal obtained from a magnetic field sensor system comprising the configuration shown in FIG. 3 can be similar to that produced by the configuration of FIG. 1. In the configuration shown in FIG. 3, however, the portion of magnetic field B seen by the sensor when the drive-current is flowing may be less than when the sensor is in-line with magnetic field B, as it was in the configuration of FIG. 1. Thus, the ratio of the portion of the field B that is modulated to the portion that is not modulated can be larger than the corresponding ratio obtained using a configuration similar to that shown in FIG. 1, which can result in greater magnetic modulation efficiency.

The sensor in the FIG. 3 configuration may detect a signal from a component of the applied field that is in a direction that is at right angles to magnetic field B. However, this field, and its resulting signal, may not be modulated in many embodiments (e.g., due to the lack of a current-driven CDFM in that direction) and so can be removed along with the other low-frequency signal components.

### Bipolar Modulation

With four CDFMs, two at each end of the sensor and at or near right angles to the direction of highest sensitivity of the sensor (e.g., indicated with an arrow in FIGS. 1, 2, 4, and 5), the CDFMs can be activated in such a manner that a steady field applied to the sensor assembly is seen by the sensor as a field that alternates in direction. In some cases, this can double the modulation efficiency of the magnetic field sensor assembly. As described below, by switching current to each pair of CDFMs on and off alternately (e.g., as shown in plots 38 and 39 of FIG. 6A and FIG. 6B, respectively), the magnetic field detected by the sensor can traverse into both positive and negative values (e.g., as shown in plot 310 of FIG. 6C).

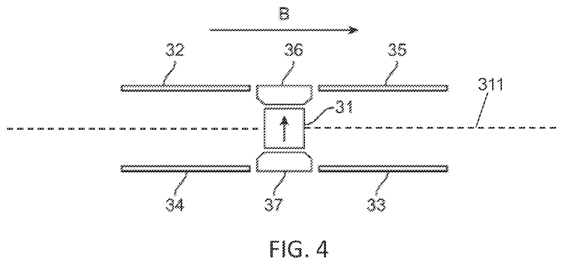

FIG. 4 shows, in schematic representation, a magnetic field sensor system comprising two pairs of CDFMs (e.g., CDFMs 32 and 33 and CDFMs 34 and 35) and a sensor 31. A second set of two CDFMs (e.g., CDFM 34 and CDFM 35) can be incorporated into a magnetic field sensor system to direct the flux through the sensor in a direction opposite that of a first set of CDFMs (e.g., CDFM 32 and CDFM 33). As configured in FIG. 4, the magnetic field sensor system can be most sensitive to magnetic fields oriented in the direction of magnetic field arrow B shown in the same figure. Such a system can be operated such that CDFMs 32 and 33 are conducting flux when CDFMs 34 and 35 are not conducting flux (e.g., by coordinating the phases of the drive currents in the first and second sets of CDFMs. In some cases, the direction of the magnetic field seen by the sensor can be opposite to the direction of the arrow drawn on the sensor when this is the case. Conversely, when CDFMs 34 and 35 are conducting magnetic flux (e.g., as a result of a lack of current in CDFM 34 and CDFM 35) and CDFMs 32 and 33 are not conducting magnetic flux (e.g., as a result of a drive current flowing through CDFM 32 and 33), the field seen by the sensor can be the same direction of the arrow drawn on the sensor. Flux guides, such as flux guide 36 and flux guide 37, can be added to improve the flux path through the sensor from the CDFMs. Flux concentrators can also be added, for instance near an end of one or more CDFMs that are distal to the sensor 31, e.g., as shown in FIG. 3. As configured in FIG. 4, a magnetic field component in the direction of field arrow B can be modulated by the CDFMs.

Plot 38 of FIG. 6A shows a possible time-dependent drive current pattern applied to CDFMs 32 and 33 and plot 39 shows an example of a drive current that can be concurrently applied to CDFMs 34 and 35. Plot 310 illustrates an example of a magnetic field signal trace that can be produced by a magnetic field sensor 31 using the drive currents shown in plots 38 and 39. It is noted that plots 38, 39, and 310 are provided as illustrative examples and that other drive currents can be provided, for example, wherein the applied drive currents have different amplitudes from one another or can have a different phase relationship to one another (e.g., not 180 degrees out of phase).

As with the other configurations described herein, the CDFMs can be curved or tilted in toward the center line 311 or otherwise arranged in order to minimize the signal from the field component in the sensor's original direction of sensitivity.

FIG. 5 shows a variation of the configuration shown in FIG. 4. In this configuration, the distal portions of off-pair CDFMs (e.g., CDFM 42 and 44, and CDFM 43 and 45) can be brought close together. In such configurations, optional flux guides (e.g., flux guides 36 and 37 shown in FIG. 4) that convey the flux to the sensor may not be necessary. The system shown in FIG. 5, which comprises magnetic field sensor 41 and magnetic flux concentrators 46 and 47 may otherwise function and be operated similarly to that of the system shown in FIG. 4. In some cases, a flux concentrator can be provided at the distal end of each CDFM.

With well-matched CDFMs, the field seen by the sensor may have no low-frequency component and the peak-to-peak strength of the modulated field may be equal to twice the peak-to-peak strength of the field obtained by the previous crossed-sensor or coaxial configurations. In some cases, e.g., when the CDFMs are well matched, the strength of the un-modulated low-frequency field may be vanishingly small. Thus, the modulation efficiency may be as high as 300%, depending on the efficiency of the CDFMs. In some embodiments, magnetic field modulation efficiency can be 20 percent to 300 percent. In some embodiments, magnetic field modulation efficiency can be 20 percent to 50 percent, 20 percent to 75 percent, 20 percent to 100 percent, 20 percent to 125 percent, 20 percent to 150 percent, 20 percent to 175 percent, 20 percent to 200 percent, 20 percent to 250 percent, 20 percent to 300 percent, 50 percent to 75 percent, 50 percent to 100 percent, 50 percent to 125 percent, 50 percent to 150 percent, 50 percent to 175 percent, 50 percent to 200 percent, 50 percent to 250 percent, 50 percent to 300 percent, 75 percent to 100 percent, 75 percent to 125 percent, 75 percent to 150 percent, 75 percent to 175 percent, 75 percent to 200 percent, 75 percent to 250 percent, 75 percent to 300 percent, 100 percent to 125 percent, 100 percent to 150 percent, 100 percent to 175 percent, 100 percent to 200 percent, 100 percent to 250 percent, 100 percent to 300 percent, 125 percent to 150 percent, 125 percent to 175 percent, 125 percent to 200 percent, 125 percent to 250 percent, 125 percent to 300 percent, 150 percent to 175 percent, 150 percent to 200 percent, 150 percent to 250 percent, 150 percent to 300 percent, 175 percent to 200 percent, 175 percent to 250 percent, 175 percent to 300 percent, 200 percent to 250 percent, 200 percent to 300 percent, or 250 percent to 300 percent. In some embodiments, magnetic field modulation efficiency can be 20 percent, 50 percent, 75 percent, 100 percent, 125 percent, 150 percent, 175 percent, 200 percent, 250 percent, or 300 percent. In some embodiments, magnetic field modulation efficiency can be at least 20 percent, 50 percent, 75 percent, 100 percent, 125 percent, 150 percent, 175 percent, 200 percent, 250 percent, or 300 percent. In some embodiments, magnetic field modulation efficiency can be at most 20 percent, 50 percent, 75 percent, 100 percent, 125 percent, 150 percent, 175 percent, 200 percent, 250 percent, or 300 percent. Modulation efficiency may be determined as the percentage of the original magnetic signal that is shifted to a different (e.g., higher) frequency.

The two CDFMs on either side of the sensor 41 (e.g., CDFM 42 and 44 and/or CDFMs 43 and 45) can be disposed within in open-ended tubes or boxes comprising an electrically conductive material. As one microwire in the tube conducts current, the flux it ejects may increase the flux in the other microwire, which may increase the performance of the system.

One benefit of bipolar field modulation is that by subtracting the ‘negative’ signal from the ‘positive’ signal, the result is a signal twice as strong with several unwanted signal components cancelling each other. A non-zero or drifting baseline, for example, may be normalized and removed from the difference signal.

### CDFM Sensors

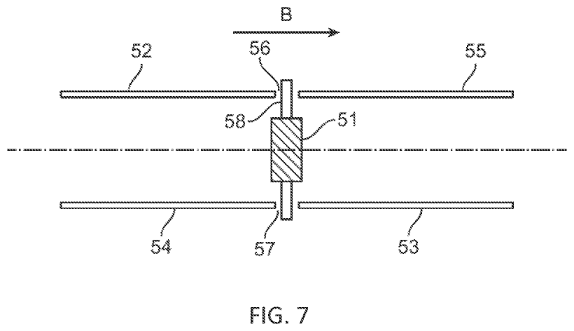

In some cases, the sensor can be replaced with a coil of wire, optionally, surrounding a piece of magnetic material, herein denoted as a ‘core’. For example, the above sensor configurations can be modified by replacing the magnetic field sensor with a coil of wire (e.g., coil 51 shown in FIG. 7), optionally surrounding a magnetic material. In some cases, when the CDFMs alter the flux at the sensor, or the core in this case, the change in magnetization of the core can induce a voltage (e.g., electromotive force, or EMF) in the coil that is at least partially disposed around (e.g., wherein the coil surrounds) the core. This EMF, which can be a measure of the change in magnetization of the core, can also be a measure of the strength of the applied magnetic field. In some cases, a magnetic field can be detected by detecting an electrical current or voltage in a coil of a magnetic field sensor system. In some embodiments, a difference between the coil-and-core sensor, or “CDFM sensor”, and the previously discussed sensor configurations may be that the CDFM sensor can induce a signal in the wire coil 51 as a result in the change of the current applied to the CDFMs. In some cases, the active microwire(s) of the CDFM sensor can be external to the coil. Having at least part of the active microwire outside of the coil can increase design flexibility and improve performance.

FIG. 7 shows a possible CDFM sensor configuration comprising four CDFMs (e.g., CDFM 52, 53, 54, and 55). In some cases, a magnetic field sensor system comprising a bipolar CDFM configuration (e.g., as shown in FIG. 4 or FIG. 5) can be modified such that the central sensor is replaced by core 58 and surrounding coil 51. Not shown in FIG. 7 are electrical leads that can be used to supply current to the CDFMs. Each of the four CDFMs can be positioned to make close magnetic contact (e.g., coupled via magnetic flux, but not necessarily physically or electrically connected) with the core at the locations 56 and 57. In some cases, when no drive-current is applied to the CDFMs, the CDFMs may conduct flux equally, and core 58 may see no net magnetization from the applied field B. When current rapidly starts flowing in one set of CDFMs, for example CDFM 52 and CDFM 53, the net magnetization of the core 58 can rapidly increase. This change in magnetization can induce an EMF in the surrounding coil 51. If the drive-current turns off rapidly or the other set of microwires 54 and 55 has the current rapidly turn on, an EMF of the opposite sign can be induced in the coil.

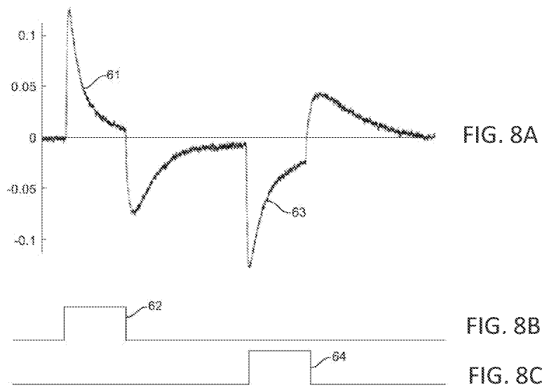

FIGS. 8A-8C shows signals acquired from a CDFM sensor configured as shown in FIG. 7. In this example, the system comprised a 2.5 mm wide Metglas foil core. Fifty turns of AWG 42 magnet wire were used to construct the coil of the system around the core. Each of the four CDFMs were single one centimeter long strands of Sency™ microwire from Aichi Steel. Each microwire extended across the foil core making good magnetic contact with the core while remaining electrically isolated from one another and the core. A magnetic field of about 20 micro-Tesla resulting from the Earth's magnetic field was present in the vicinity of the sensor. FIG. 8A shows a plot of the signal current as a function of time from the coil into a 50-ohm resistor shunted across the terminals of the coil. In this example, signal 61 is the result of a first current pulse 62 through CDFMs 52 and 53 of FIG. 7, and signal 63 is the result of a second current pulse 64 through CDFMs 54 and 55 of FIG. 7. The two current pulses 62 and 64 are plotted below the corresponding signals 61 and 63. The drive-current through the CDFMs was 100 mA and the duration of the pulses was 1.5 micro-seconds.

Signals 61 and 63 can have similar shapes as signals described in U.S. Patent Publication No. US 2020/0256930 A1 and PCT Patent Publication No. WO2020167551A1, which are incorporated herein in its entirety and for all purposes, for current-sensing GMI sensors. The signal can rapidly increase when the drive-current turns on and then decays exponentially with time. In some cases, the signal can then rapidly increase again, but with the opposite polarity, e.g., when the drive-current turns off. Note that the current pulse 62 can create a positive-going signal and current pulse 64 can create a similar but negative-going signal. When the CDFM sensor was rotated so that the Earth's field was in the other direction, the polarity of both signals reversed. The results presented in FIGS. 8A-8C demonstrate the ability of this CDFM sensor configuration to reverse the polarity, at the central sensor, of the applied magnetic field. This configuration is an example of the use of CDFMs to control the intensity and direction of the applied magnetic field at the sensor. The drive-current pattern and the signal shapes described above and shown in FIGS. 8A-8C represent an example, with other options possible and easily implemented, based on the present disclosure. For example, out-of-phase sinusoidal drive currents may be used in a magnetic field sensor system described herein. Drive currents may also be designed and selected that result in a sinusoidal signal from the coil.

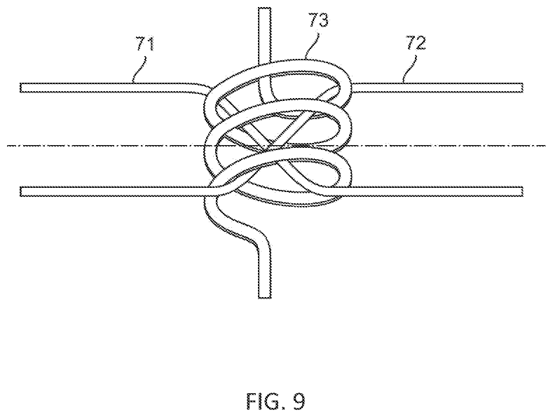

FIG. 9 shows a second configuration of a magnetic field sensor system comprising a CDFM sensor. Microwires 71 and 72 can be passed through the central coil 73 in opposite directions in some embodiments. It is noted that FIG. 9 depicts the coil as having only three turns for clarity purposes, whereas in practice, the coil would have many turns (e.g., at least 10 turns, at least 50 turns, at least 100 turns, at least 200 turns, at least 300 turns, at least 400 turns, or at least 500 turns). In some cases, an EMF can be induced in the coil if the drive-current in either CDFM 71 or CDFM 72 turns on rapidly, and the polarity of the signal can depend upon the direction of the applied field and upon which CDFM turned on.

### Multi-Axis Configurations

In some cases, a magnetic field sensor system can detect a magnetic field in a plurality of directions simultaneously. In some cases, a magnetic field sensor system can comprise a muti-axis sensor. In some cases, a magnetic field sensor system can comprise a plurality of co-axial (or substantially parallel) CDFMs and one or more additional CDFMs disposed at an angle to the plurality of co-axial or substantially parallel CDFMs. In some cases, such a sensor configuration may be referred to as a multi-axis sensor. In some cases, the one or more additional CDFMs can be disposed at a non-zero angle (e.g., an angle from 15 degrees to 165 degrees or from 45 degrees to 90 degrees) relative to one or more of the pluralities of co-axial or substantially parallel CDFMs. For example, a first and second CDFM can be oriented such that a longitudinal axis of the first CDFM (e.g., which can run from a proximal end of the CDFM to a proximal end of the CDFM, for instance, through a center point of the CDFM) can be at a non-zero angle relative to a longitudinal axis of a second CDFM) is at a non-zero angle relative to a longitudinal axis of the second CDFM. In some cases, a first and second CDFM can be oriented such that a longitudinal axis of the first CDFM is at an angle of zero (e.g., axially in-line or parallel) relative to a longitudinal axis of the second CDFM. By adding additional and similar CDFMs in a different direction, such as in a direction perpendicular to the page in FIG. 5, and by switching on and off drive current to one or more sets of CDFMs oriented in each of the different directions, a single sensor can measure the field in multiple (e.g., two or three) different directions. In some embodiments, a first CDFM (or first set of CDFMs) can be oriented orthogonal to a second CDFM (or second set of CDFMs), for example, to provide maximum detection of orthogonal aspects of a multi-dimensional magnetic field. In some cases, a multi-axis configuration comprises three CDFMs (or three sets of CDFMs, e.g., wherein a first CDFM is co-axial or substantially parallel to one or more CDFMs in the same set). In some cases, two or more of a first CDFM (or first set(s) of co-axial or substantially parallel CDFMs), a second CDFM (or second set(s) of co-axial or substantially parallel CDFMs), and a third CDFM (or third set(s) of co-axial or substantially parallel CDFMs) can be oriented orthogonal to one another in a magnetic field detection system. Orienting two or more sets of CDFMs perpendicularly to one another can maximize the detection of magnetic fields passing through a point. A magnetic field sensor can be positioned at a point of intersection between of a first and second set of CDFMs. In some cases, one can add even more CDFMs (e.g., at different angles to the magnetic field sensor) in order to have a single sensor observe the field in three or more directions.

Various drive current patterns can be used to modulate the electrical current within a component of a magnetic field sensor system. An amplitude and/or frequency of a drive current pattern can correlate to the amplitude and/or frequency with which a magnetic field is modulated.

For instance, a drive current pattern (e.g., a periodic or oscillatory drive current pattern) with a higher maximum amplitude (and, in some cases, a lower minimum amplitude) may evoke a modulated magnetic field with a greater dynamic range and/or with more rapid falloff and/or rises in magnetic flux. In many cases, the frequency of oscillation or reversal of a drive current in a magnetically conductive component of a magnetic field sensor system can determine, at least in part, the frequency of a modulated magnetic field.

In a multi-axis sensor, each magnetic field signal of two or more detected magnetic field signals, e.g., which have been detected in a respective direction of the two or more axial directions using one or more set of CDFMs oriented in each of the respective directions, can be acquired separately by time sharing the drive-currents (e.g., temporally separating the application of drive current to a CDFM or set of CDFMs oriented in each direction). Alternatively or additionally, the two magnetic field signals detected in each different direction can be distinguished from one other by driving CDFM(s) in each different direction with drive current patterns having different drive frequencies (e.g., and separately processing the signals from those frequency bands after raw magnetic field data acquisition with the sensor(s)).

The electrical drive-current in a CDFM and the electrically conductive components connected to it can produce magnetic fields that may affect the field seen by the sensor. These fields from a CDFM could potentially affect the data pertaining to a magnetic field of interest since the drive-current may be flowing when the measurement is being performed. The impact of additional magnetic fields on magnetic field sensor readings can be minimized through careful design and placement of conductors (e.g., CDFMs, flux guides, and/or flux concentrators). For example, positioning leads for delivering a drive current to the CDFMs in close proximity to one another (e.g., evaluated at the point of coupling with the CDFMs) minimizes field generation. In some cases, selecting a drive-current to minimize the production of stray fields during application to a CDFM can help to minimize the effect of such stray fields on magnetic field sensor readings. Alternatively or additionally, passive electromagnetic shielding (e.g., comprising an open-ended conductor disposed around the CDFMs) can be used to minimize the impact of additional magnetic fields produced by CDFMs on the sensor(s).

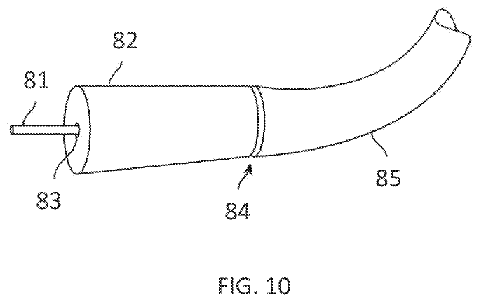

A CDFM can be incorporated into the end of a coaxial cable (e.g., a small-diameter semi-rigid coaxial cable). In some embodiments, a coaxial CDFM can be configured shown in FIG. 10. A microwire (e.g., of a CDFM) can be enclosed within a conductor, e.g., as shown in FIG. 10. In some cases, the conductor can serve as a return path for a drive current. Enclosing a microwire (e.g., a CDFM microwire) within a conductor can reduce the impact of a magnetic field generated by the drive-current on the magnetic field detected by the sensor. In some cases, enclosing a microwire (e.g., a CDFM microwire) within a conductor (e.g., as shown in FIG. 10) can improve sensitivity of magnetic field measurements, for example, by shielding the sensor from a magnetic field generated by the drive current in the microwire. In some cases, element 81 is one end the microwire shown extending out of the bottom of the conducting sleeve or cup 82. The rest of the microwire may be within the cup 82. The microwire may be electrically connected to the cup at the center of its bottom at location 83. The cup 82 can be the return path for the CDFM drive-current. The other end of the cup (e.g., the top), can be electrically connected to the coax cable shield (e.g., cladding) at location 84. With the return current coaxial with the drive current, the field generated by the drive-current and its electrical leads will be minimized. The section of microwire 81 extending beyond the bottom of the cup can act as a flux guide taking the flux close to the sensor. The other end of the internal microwire can be electrically connected to the coaxial cable's center conductor. Heat-sink compound within the cup can help dissipate the heat from the microwire.

### Microwires

The term “microwire” can include cross-sectional shapes other than wires with small-diameters and round cross sections. In some cases, the microwire can comprise material that changes its magnetic permeability when carrying an electrical current. A discussion of microwire that changes permeability when carrying an electrical current is described in U.S. Patent Publication No. US 2020/0256930 A1 and PCT Patent Publication No. WO2020167551A1, which are incorporated herein in its entirety and for all purposes.

Multiple parallel microwires can be used instead of a single microwire as shown in the drawings. This may have benefits, including increasing the flux carrying capacity and thus increasing the strength of the applied field that the microwire (e.g., CDFM microwire) can handle.

A drive-current can be applied to components of magnetic field sensor systems (e.g., CDFMs) in pulses that are short relative to the time between them, for example, to reduce the rate of energy deposition, as microwires may have a high electrical resistivity so that the current used to reduce their permeability may deposit a significant amount of heat. Also, the microwires may have a small cross-sectional area so that a small amount of deposited heat causes a significant temperature rise. A heat-sink compound or structure or other means and methods of heat removal can be employed, e.g., to conduct heat away from current-driven microwires. Optionally, microwires with higher electrical conductivity can be employed to reduce heating of the microwires caused by drive currents.

Ideally, a CDFM microwire can have high permeability when the drive current is zero and low permeability when the drive current is applied to the CDFM.

### Applications

The present disclosure provides embodiments of devices, systems, and methods useful for measuring and assessing cardiac function and health. A major advantage of the magnetic field sensor systems provided herein is that magnetic field detection can be performed exterior to the chest cavity (e.g., noninvasively and without the application of electrical leads to the skin surface).

One of skill in the art will appreciate that the devices and methods disclosed herein may be used in other technological fields for measuring magnetic fields, including but not limited to agriculture, industrial applications, national defense, biology, medicine, aerospace, interplanetary research, videogames, geological survey, telecommunications, determining magnetic fields and/or electrical fields in electrical networks and systems, and reading information on computer media (e.g., information stored on computer hard drives).

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical values given herein should also be understood to include about or approximately that value, unless the context indicates otherwise. For example, if the value “10” is disclosed, then “about 10” is also disclosed. Any numerical range recited herein is intended to include all sub-ranges subsumed therein. It is also understood that when a value is disclosed that “less than or equal to” the value, “greater than or equal to the value” and possible ranges between values are also disclosed, as appropriately understood by the skilled artisan. For example, if the value “X” is disclosed the “less than or equal to X” as well as “greater than or equal to X” (e.g., where X is a numerical value) is also disclosed. It is also understood that the throughout the application, data is provided in a number of different formats, and that this data, represents endpoints and starting points, and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

Although the terms “first” and “second” may be used herein to describe various features/elements (including steps), these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

When used in the following claims, the terms “comprise”, “include”, “have” and their conjugates mean “including but not limited to.” Throughout this specification and the claims which follow, unless the context requires otherwise, the word “comprise”, and variations such as “comprises” and “comprising” means various components can be co-jointly employed in the methods and articles (e.g., compositions and apparatuses including device and methods). For example, the term “comprising” will be understood to imply the inclusion of any stated elements or steps but not the exclusion of any other elements or steps.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

What is claimed is:

1. A system for detecting a magnetic field comprising:
a magnetic field sensor; and
one or more current-driven flux modulators (CDFMs), each CDFM comprising a magnetically soft material; and
one or more current sources electrically coupled to the one or more of CDFMs.

2. The system of claim 1, wherein a magnetic permeability of the magnetically soft material decreases when electrical current is applied to the CDFM.

3. The system of claim 1, wherein a direction of sensitivity of the magnetic field sensor is oriented at an angle of zero relative to a longitudinal axis of the one or more CDFMs defined by a proximal end and a distal end of the CDFMs.

4. The system of claim 1, wherein a direction of sensitivity of the magnetic field sensor is oriented at a non-zero angle relative to a longitudinal axis of one or more CDFMs defined by a proximal end and a distal end of the CDFM.

5. The system of claim 1, wherein a proximal end of the one or more CDFMs is positioned proximal to the magnetic field sensor.

6. The system of claim 1, wherein at least one CDFM of the one or more CDFMs comprises a microwire.

7. The system of claim 1, wherein a first current source of the one or more current sources provides a first electrical drive current having a first repetitive electrical drive current pattern.

8. The system of claim 7, wherein the first repetitive electrical drive current pattern comprises an oscillatory waveform.

9. The system of claim 8, wherein the oscillatory waveform comprises a frequency greater than a frequency of a magnetic field signal of interest.

10. The system of claim 1, wherein a second current source of the one or more current sources is configured to provide a second repetitive electrical drive current having a different frequency than a frequency of the first repetitive electrical drive current.

11. The system of claim 10, wherein the system is configured to apply the first repetitive electrical drive current to a first CDFM and the second repetitive electrical drive current to a second CDFM, wherein a longitudinal axis of the first CDFM and a longitudinal axis of the second CDFM are oriented at a non-zero angle with respect to one another.

12. The system of claim 1, wherein the magnetic field sensor comprises a magnetoresistive sensor.

13. The system of claim 1, wherein the magnetoresistive sensor is a giant magnetoresistive sensor or a tunneling magnetoresistive sensor.

14. The system of claim 1, wherein the magnetic field sensor comprises a giant magnetoimpedance sensor.

15. The system of claim 1, wherein the magnetic field sensor comprises a coil comprising an electrically conductive material and a core comprising a magnetically soft material, wherein the coil is disposed at least partially around the core.

16. The system of claim 15, wherein the system is configured to detect the magnetic field based on an electrical current or voltage in the coil.

17. A device for controlling the flow of magnetic flux from a first location to a second location, said device comprising:
an elongate flux modulator comprising a first electrical connection point at a first end of the elongate flux modulator and a second electrical connection point at a second end of the elongate flux modulator, wherein the first and second electrical connection points are couplable to an electrical current source, and
wherein the elongate flux modulator comprises a magnetically soft material and wherein the magnetically soft material changes magnetic permeability upon the application of an electrical current.

18. The device of claim 17, wherein the second location comprises a magnetic field sensor.

19. The device of claim 17 or claim 18, wherein the magnetic permeability of the magnetically soft material decreases upon application of the electrical current.

20. The device of claim 17, wherein the magnetic permeability of the magnetically soft material increases upon removal of an electrical current applied to the magnetically soft material.

21. A method of detecting a magnetic field comprising:
providing a magnetic field sensor within a magnetic field;
providing one or more current-driven flux modulators (CDFMs) proximal to the magnetic field sensor, each CDFM of the one or more CDFMs comprising a magnetically permeable material;
applying one or more electrical drive currents to the one or more CDFMs; and
detecting the magnetic field with the magnetic field sensor.

22. The method of claim 21, wherein applying one or more electrical drive currents changes the magnetic permeability of the one or more CDFMs.

23. The method of claim 22, wherein applying the one or more electrical drive currents decreases the magnetic permeability of the one or more CDFMs.

24. The method of claim 21, wherein the electrical drive current comprises an oscillatory waveform.

25. The method of claim 21, wherein the one or more electrical drive currents comprises an oscillation frequency greater than a frequency of the magnetic field prior to applying the one or more electrical drive currents to the one or more CDFMs.

26. The method of claim 21, wherein a proximal end of the one or more CDFMs is positioned proximal to the magnetic field sensor.

27. The method of claim 21, further comprising filtering a signal obtained by detecting the magnetic field.

28. The method of claim 27, wherein the filtering comprises applying a high pass filter to the signal.

29. The method of claim 21, wherein the one or more electrical drive currents comprises a plurality of electrical drive currents and wherein a first electrical drive current of the plurality of electrical drive currents comprises a repetitive drive current pattern with a different frequency than a frequency of a second electrical drive current of the plurality of electrical drive currents.

30. The method of claim 29, wherein the first electrical drive current is applied to a first CDFM and a second electrical drive current is applied to a second CDFM, wherein a longitudinal axis of the first CDFM and a longitudinal axis of the second CDFM are oriented at a non-zero angle with respect to one another.

31. The method of claim 21, wherein the magnetic field sensor comprises a magnetoresistive sensor.

32. The method of claim 21, wherein the magnetic field sensor comprises a giant magnetoresistive sensor or a tunneling magnetoresistive sensor.

33. The method of claim 21, wherein the magnetic field sensor comprises a giant magnetoimpedance sensor.

34. The method of claim 21, wherein the CDFM comprises a microwire.

35. The method of claim 21, wherein the magnetic field sensor comprises a coil comprising an electrically conductive material and a core comprising a magnetically soft material, wherein the coil is disposed at least partially around the core.

36. The method of claim 35, further comprising detecting the magnetic field by detecting an electrical current or voltage in the coil.
